(19) United States
(12) Patent Application Publication
(10) Pub. No.: US 2025/0220964 A1
(43) Pub. Date: Jul. 3, 2025

(54) THIN FILM TRANSISTOR AND DISPLAY APPARATUS COMPRISING THE SAME

(71) Applicant: LG Display Co., Ltd., Seoul (KR)

(72) Inventors: Dohyung LEE, Paju-si (KR); HongRak CHOI, Paju-si (KR); Dohyun KWAK, Paju-si (KR)

(21) Appl. No.: 18/979,258

(22) Filed: Dec. 12, 2024

(30) Foreign Application Priority Data
Dec. 28, 2023 (KR) 10-2023-0195028

(51) Int. Cl. H10D 30/67; H10D 30/01; H10D 86/01; H10D 86/40; H10D 86/60; H10K 59/121

(52) U.S. Cl. CPC H10D 30/6734; H10D 30/0312; H10D 30/6736; H10D 30/6755; H10D 30/6757; H10D 86/0221; H10D 86/0231; H10D 86/423; H10D 86/451; H10D 86/60; H10K 59/1213

(57) ABSTRACT

A thin film transistor and a display apparatus including the thin film transistor are provided. The thin film transistor includes a first gate electrode, a first gate insulating layer on the first gate electrode, an active layer on the first gate insulating layer, a second gate insulating layer on the active layer, and a second gate electrode on the second gate insulating layer, wherein the active layer includes a channel portion, and the channel portion includes a first channel portion overlapping the first gate electrode and a second channel portion overlapping the second gate electrode, and wherein the first gate electrode and the second gate electrode do not overlap each other in a plan view.

### CROSS-REFERENCE TO RELATED APPLICATIONS

This application claims the benefit and priority of the Korean Patent Application No. 10-2023-0195028 filed on Dec. 28, 2023, which is hereby incorporated by reference, for all purposes, as if fully set forth herein.

### TECHNICAL FIELD

The present disclosure relates to a thin film transistor and a display apparatus including the same. In detail, an embodiment of the present disclosure relates to a thin film transistor having a double gate structure and a display apparatus including the same.

### DESCRIPTION OF THE RELATED ART

Since a thin film transistor can be manufactured on a glass substrate or plastic substrate, it is widely used as a switching element or driving element in a display apparatus such as a liquid crystal display apparatus or an organic light emitting display apparatus.

Based on the material constituting the active material layer, the thin film transistors may be classified as an amorphous silicon thin film transistor in which amorphous silicon is used as the active material layer, a polycrystalline silicon thin film transistor in which polycrystalline silicon is used as the active material layer, and an oxide semiconductor thin film transistor in which oxide semiconductor used as the active material layer.

### BRIEF SUMMARY

Among the various types of thin film transistors in the related art, an oxide semiconductor thin film transistor (oxide semiconductor TFT), which has a high mobility and can have large resistance changes depending on the oxygen content, has an advantage in that desired properties may easily be obtained. In addition, the manufacturing cost of an oxide semiconductor thin film transistor is low because the oxide constituting the active layer can be formed at a relatively low temperature during the manufacturing process of the oxide semiconductor thin film transistor. Due to the nature of oxide, oxide semiconductor is transparent, thus the oxide semiconductor thin film transistor is advantageous for embodying a transparent display apparatus.

The display apparatus may include a switching transistor and a driving transistor. In general, it is advantageous for the switching transistor to have a small s-factor (threshold swing) to improve on-off characteristics. In the meantime, it is advantageous for the driving transistor to have a large s-factor to express gray scale. However, since thin film transistors generally have a small s-factor to ensure on-off characteristics, when these thin film transistors are applied to a driving transistor of a display apparatus, there is difficulty in expressing gray scale.

Accordingly, the inventors of the present disclosure have appreciated that a thin film transistor with a large s-factor is beneficial in order to easily express gray scale when the thin film transistor is applied to a driving transistor of a display apparatus. Therefore, an aspect of the present disclosure is to provide a thin film transistor with a large s-factor. An aspect of the present disclosure is to provide a thin film transistor that has a large s-factor in the threshold voltage section and can easily express gray scale.

In addition, an aspect of the present disclosure is to provide a thin film transistor with excellent current characteristics.

Another aspect of the present disclosure is to provide a display apparatus comprising a thin film transistor with a large s-factor as a driving transistor, and thus having an excellent gray scale expression ability.

In accordance with an aspect of the present disclosure, the above and other objects can be accomplished by the provision of a thin film transistor including a first gate electrode, a first gate insulating layer on the first gate electrode, an active layer on the first gate insulating layer, a second gate insulating layer on the active layer, and a second gate electrode on the second gate insulating layer, wherein the active layer includes a channel portion, a first connection portion contacting one side of the channel portion, and a second connection portion contacting the other side of the channel portion, wherein the channel portion may include a first channel portion overlapping the first gate electrode, and a second channel portion overlapping the second gate electrode, and wherein the first gate electrode and the second gate electrode do not overlap each other in a plan view.

The first channel portion may not overlap the second gate electrode, and the second channel portion may not overlap the first gate electrode.

The first channel portion and the second channel portion may be spaced apart from each other is a plan view.

The separation distance between the first channel portion and the second channel portion may be 0 μm or more and 1 μm or less.

The first gate insulating layer may have a thickness of 2 to 3 times a thickness of the second gate insulating layer.

When a direction connecting the first connection portion and the second connection portion in a plan view is called a longitudinal direction of the channel portion, and a direction perpendicular to the longitudinal direction of the channel portion is called a width direction of the channel portion, a ratio of a width of the first channel portion to a width of the second channel portion may be in a range of 8:2 to 2:8.

A ratio of a length of the first channel portion to a length of the second channel portion may be in a range of 1:2 to 2:1.

The width of the first channel portion may be larger than the width of the second channel portion.

The length of the first channel portion may be smaller than the length of the second channel portion.

The length of the first channel portion may be greater than the length of the second channel portion.

The first channel portion and the second channel portion may have a same length.

The first channel portion and the second channel portion may have a same width.

The width of the first channel portion may be smaller than the width of the second channel portion.

The length of the first channel portion may be greater than the length of the second channel portion.

The active layer may include at least one of IGZO (InGaZnO)-based oxide semiconductor material, IZO (InZnO)-based oxide semiconductor material, ITZO (InSnZnO)-based oxide semiconductor material, FIZO (FeInZnO)-based oxide semiconductor material, ZnO-based oxide semiconductor material, SIZO (SiInZnO)-based oxide semiconductor material, ZnON (Zn-Oxynitride)-based oxide semiconductor material, GZO (GaZnO)-based oxide semiconductor material, IGO (InGaO)-based oxide semiconductor material, IGZTO (InGaZnSnO)-based oxide semiconductor material, GZTO (GaZnSnO)-based oxide semiconductors and IWZO (InWZnO)-based oxide semiconductor material.

Another embodiment of the present disclosure provides a display apparatus including a pixel driving circuit and a display element connected to the pixel driving circuit, wherein the pixel driving circuit includes the thin film transistor described above.

The pixel driving circuit includes a driving transistor and a switching transistor, and the thin film transistor may be applied to the driving transistor.

### Technical Effects of the Disclosure

A thin film transistor according to an embodiment of the present disclosure includes gate electrodes that are disposed on both sides of the active layer and do not overlap each other, and thus the thin film transistor can have a large s-factor value.

A display apparatus according to an embodiment of the present disclosure can have excellent gray scale expression capabilities by using a thin film transistor with a large s-factor as a driving transistor.

In addition to the above-mentioned effects, other features and advantages of the present disclosure are described below, or can be clearly understood by those skilled in the art from the description.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the explanation serve to explain the principle of the disclosure. The above and other objects, features and other advantages of the present disclosure will be more clearly understood from the following detailed description taken in conjunction with the accompanying drawings.

FIG. 1A is a plan view of a thin film transistor according to an embodiment of the present disclosure.

FIG. 1B is a cross-sectional view along a line I-I′ of FIG. 1A.

FIG. 1C is a cross-sectional view along a line II-II′ of FIG. 1A.

FIG. 2A is a plan view of a thin film transistor according to another embodiment of

FIG. 2B is a cross-sectional view along a line III-III′ of FIG. 2A.

FIG. 2C is a cross-sectional view along a line IV-IV′ of FIG. 2A.

FIG. 3A and FIG. 3B are cross-sectional views of a thin film transistor according to another embodiment of the present disclosure, respectively.

FIG. 4 is a cross-sectional view of a thin film transistor according to another embodiment of the present disclosure.

FIG. 5 is a cross-sectional view of a thin film transistor according to another embodiment of the present disclosure.

FIG. 6 is a plan view of a thin film transistor according to another embodiment of the present disclosure.

FIG. 7 is a plan view of a thin film transistor according to another embodiment of the present disclosure.

FIG. 8 is a plan view of a thin film transistor according to another embodiment of the present disclosure.

FIG. 9 is a plan view of a thin film transistor according to another embodiment of the present disclosure.

FIG. 10 is a plan view of a thin film transistor according to another embodiment of the present disclosure.

FIG. 11 is a plan view of a thin film transistor according to another embodiment of the present disclosure.

FIG. 12 is a plan view of a thin film transistor according to another embodiment of the present disclosure.

FIG. 13 is a plan view of a thin film transistor according to another embodiment of the present disclosure.

FIGS. 14A, 14B, and 14C are threshold voltage graphs of thin film transistors, respectively.

FIGS. 15A, 15B, and 15C are threshold voltage graphs of thin film transistors, respectively.

FIGS. 16A, 16B, and 16C are threshold voltage graphs of thin film transistors, respectively.

FIGS. 17A to 17G are schematic process diagrams for a method of manufacturing a thin film transistor according to an embodiment of the present disclosure.

FIG. 18 is a schematic diagram of a display apparatus according to another embodiment of the present disclosure.

FIG. 19 is a circuit diagram of one pixel of FIG. 18.

FIG. 20 is a plan view of the pixel of FIG. 19.

FIG. 21 is a cross-sectional view along a line V-V′ of FIG. 20.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a dimension (e.g., length, width, height, thickness, radius, diameter, area, etc.), a ratio, an angle, and a number disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more portions may be arranged between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to partition one element from another. For example, a first element could be termed a second element, and, similarly, a second element could be termed a first element, without departing from the scope of the present disclosure.

The term “at least one” should be understood as including any and all combinations of one or more of the associated listed items. Namely, the text “at least one of A and B” as used herein should be understood to include at least one of A, or at least one of B, or at least one of both A and B. This similarly applies to “at least one of A, B, and C” and so forth. For example, the meaning of “at least one of a first item, a second item, and a third item” denotes the combination of all items proposed from two or more of the first item, the second item, and the third item as well as the first item, the second item, or the third item.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, a thin film transistor and a display apparatus including the same according to an embodiment of the present disclosure will be described in detail with reference to the attached drawings. In the drawings, the same or similar elements are denoted by the same reference numerals even though they are depicted in different drawings.

In the embodiments of the present disclosure, a source electrode and a drain electrode are distinguished from each other, for convenience of description. However, the source electrode and the drain electrode may be used interchangeably. The source electrode may be the drain electrode, and the drain electrode may be the source electrode. Also, the source electrode in any embodiment of the present disclosure may be the drain electrode in another embodiment of the present disclosure, and the drain electrode in any embodiment of the present disclosure may be the source electrode in another embodiment of the present disclosure.

In some embodiments of the present disclosure, for convenience of explanation, a source connection portion and a source electrode are distinguished, and a drain connection portion and a drain electrode are distinguished, but the embodiments of the present disclosure are not limited thereto. The source connection portion may be a source electrode, and the drain connection portion may be a drain electrode. In addition, the source connection portion may be a drain electrode, and the drain connection portion may be a source electrode.

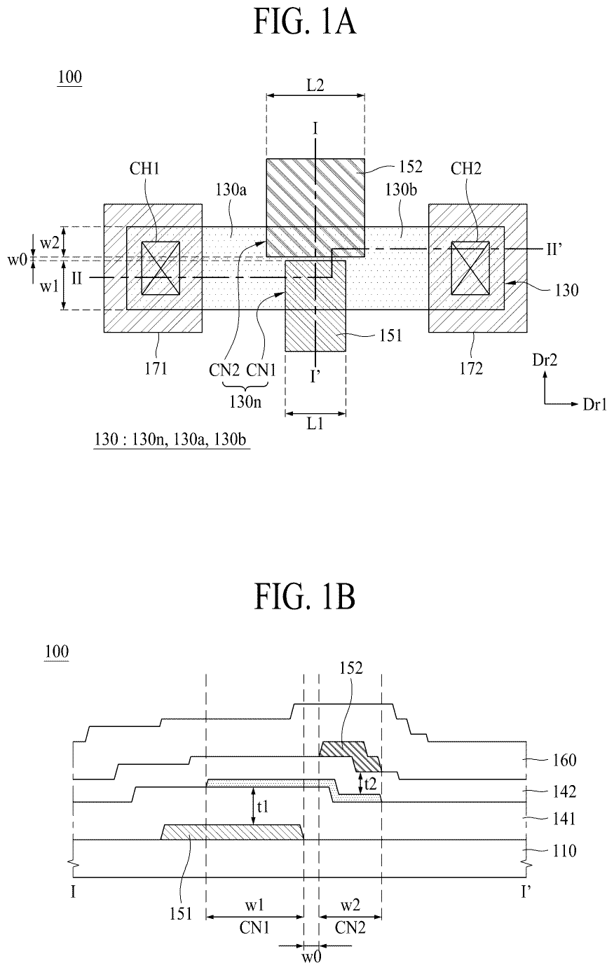

FIG. 1A is a plan view of a thin film transistor 100 according to an embodiment of the present disclosure, FIG. 1B is a cross-sectional view along a line I-I′ of FIG. 1A, and FIG. 1C is a cross-sectional view along a line II-II′ of FIG. 1A.

Referring to FIGS. 1A, 1B, and 1C, the thin film transistor 100 according to an embodiment of the present disclosure includes a first gate electrode 151, a first gate insulating layer 141 on the first gate electrode 151, an active layer 130 on the first gate insulating layer 141, a second gate insulating layer 142 on the active layer 130, and a second gate electrode 152 on the second gate insulating layer 142.

Referring to FIGS. 1B and 1C, the thin film transistor 100 according to an embodiment of the present disclosure may be disposed on a base substrate 110.

Glass or plastic may be used as the base substrate 110. A transparent plastic with flexible properties, for example, polyimide, may be used as the plastic. When polyimide is used as the base substrate 110, considering that a high temperature deposition process is performed on the base substrate 110, heat-resistant polyimide that can withstand high temperatures may be used.

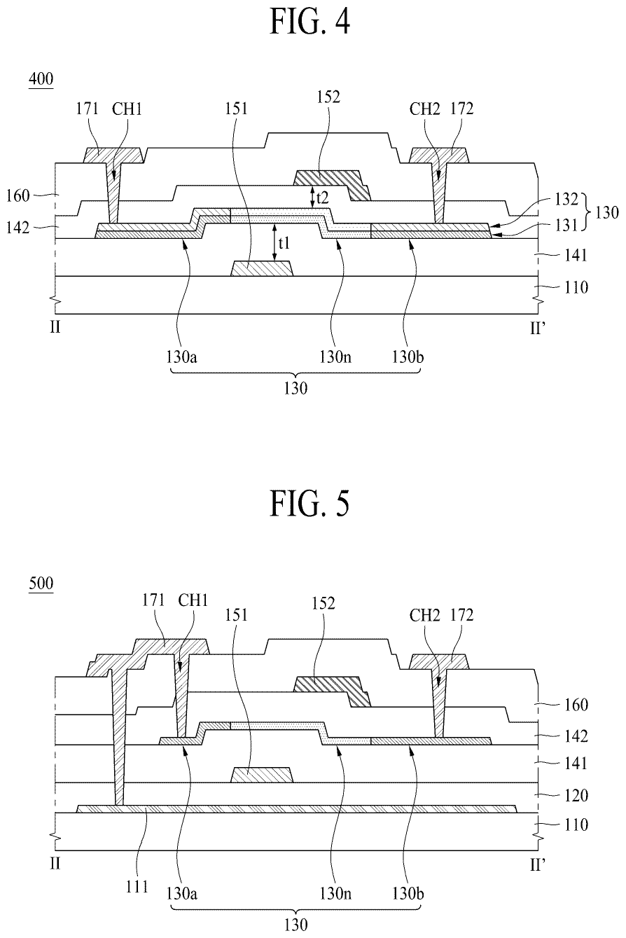

Although not shown in FIGS. 1B and 1C, a buffer layer may be disposed on the base substrate 110 (see FIG. 5). The buffer layer can protect the active layer 130. An upper surface over the base substrate 110 can be flat by the buffer layer.

A first gate electrode 151 is disposed on the base substrate 110.

The first gate electrode 151 may include at least one of an aluminum-based metal such as aluminum (A1) or an aluminum alloy, a silver-based metal such as silver (Ag) or a silver alloy, a copper-based metal such as copper (Cu) or a copper alloy, a molybdenum-based metal such as molybdenum (Mo) or molybdenum alloy, chromium (Cr), tantalum (Ta), neodymium (Nd), and titanium (Ti). The first gate electrode 151 may have a multilayer structure including at least two conductive films each having different physical properties.

A first gate insulating layer 141 is disposed on the first gate electrode 151. The first gate insulating layer 141 protects the active layer 130.

The first gate insulating layer 141 may include at least one of silicon oxide, silicon nitride, and metal-based oxide. The first gate insulating layer 141 may have a single-layer structure or a multi-layer structure. According to an embodiment of the present disclosure, the first gate insulating layer 141 can act as a buffer layer to block oxygen (O2) or moisture (H2O) penetrating from the base substrate 110. To this end, the first gate insulating layer 141 may be made of an oxide such as silicon oxide.

Referring to FIGS. 1B and 1C, the first gate insulating layer 141 may be disposed on the entire surface of the base substrate 110 without being patterned.

The active layer 130 is disposed on the first gate insulating layer 141. At least a portion of the active layer 130 overlaps the first gate electrode 151.

The active layer 130 may include a semiconductor material. According to an embodiment of the present disclosure, the active layer 130 may include an oxide semiconductor material.

The active layer 130 may include at least one of an IGZO (InGaZnO)-based oxide semiconductor material, an IZO (InZnO)-based oxide semiconductor material, an ITZO (InSnZnO)-based oxide semiconductor material, a FIZO (FeInZnO)-based oxide semiconductor material, a ZnO-based oxide semiconductor material, a SIZO (SiInZnO)-based oxide semiconductor material, a ZnON (Zn-Oxynitride)-based oxide semiconductor material, a GZO (GaZnO)-based oxide semiconductor material, a IGO (InGaO)-based oxide semiconductor material, a IGZTO (InGaZnSnO)-based oxide semiconductor material, a GZTO (GaZnSnO)-based oxide semiconductor material and an IWZO (InWZnO)-based oxide semiconductor material.

According to an embodiment of the present disclosure, the active layer 130 includes a channel portion 130n, a first connection portion 130a, and a second connection portion 130b. The first connection portion 130a contacts one side of the channel portion 130n, and the second connection portion 130b contacts the other side of the channel portion 130n.

The first connection portion 130a and the second connection portion 130b may be formed by selective conductorization to the active layer 130. In detail, the first connection portion 130a and the second connection portion 130b may be formed by selective conductorization of the oxide semiconductor material constituting the active layer 130. The first connection portion 130a and the second connection portion 130b may be referred to as conductorized portions.

According to an embodiment of the present disclosure, selective conductorization refers to improving conductivity of a selected portion of the active layer 130 or providing conductivity to a selected portion of the active layer 130. Imparting conductivity to a selected portion may also be referred to as selective conductorization. A portion may be selectively conductorized by selective conductorization. According to an embodiment of the present disclosure, selective conductorization can be achieved by doping a selected region with a dopant. Accordingly, the first connection portion 130a and the second connection portion 130b may include a dopant.

According to an embodiment of the present disclosure, doping may be performed by implanting dopant ions. According to an embodiment of the present disclosure, the dopant for conductorization may include at least one of boron (B), fluorine (F), phosphorus (P), and hydrogen (H).

Selective conductorization may also be referred to as selective metallization, and the first connection portion 130a and the second connection portion 130b may be referred to as metallized portions.

The selectively conductorized portion of the active layer 130 has excellent electric conductivity and thus can function as a wiring portion.

However, an embodiment of the present disclosure is not limited thereto, and conductivity may be imparted to the first connection portion 130a and the second connection portion 130b by other methods. For example, conductivity may be imparted to the first connection portion 130a and the second connection portion 130b through plasma processing. In detail, during the patterning process of the second gate insulating layer 142 or the second gate electrode 152, selective conductorization may be performed through plasma processing to form the first connection portion 130a and the second connection portion 130b.

According to an embodiment of the present disclosure, the first connection portion 130a of the active layer 130 may be a source region, and the second connection portion 130b may be a drain region. However, an embodiment of the present disclosure is not limited thereto, and the first connection portion 130a may be a drain region and the second connection portion 130b may be a source region.

According to an embodiment of the present disclosure, a region of the active layer 130, which is not conductorized, may become a channel portion 130n.

According to an embodiment of the present disclosure, the channel portion 130n may include a first channel portion CN1 overlapping the first gate electrode 151 and a second channel portion CN2 overlapping the second gate electrode 152. The gate electrodes 151 and 152 and the channel portion 130n will be described later.

A second gate insulating layer 142 is disposed on the active layer 130. The second gate insulating layer 142 protects the channel portion 130n.

The second gate insulating layer 142 may include at least one of silicon oxide, silicon nitride, and metal-based oxide. The second gate insulating layer 142 may have a single-layer structure or a multi-layer structure. The second gate insulating layer 142 may have the same composition as the first gate insulating layer 141 or may have a different composition with the first gate insulating layer 141.

Referring to FIGS. 1B and 1C, the second gate insulating layer 142 may be disposed on the entire surface over the base substrate 110. In this case, the second gate insulating layer 142 may not be patterned, and selected portions of the active layer 130 may be selectively conductorized by, for example, selective ion doping, selective hydrogen implantation, or selective ultraviolet irradiation. By the selective conductorization, the first connection portion 130a and the second connection portion 130b can be formed.

However, an embodiment of the present disclosure is not limited thereto, and the second gate insulating layer 142 may have a patterned structure.

The second gate electrode 152 is disposed on the second gate insulating layer 142. The second gate electrode 152 overlaps at least a portion of the active layer 130.

The second gate electrode 152 may include at least one of an aluminum-based metal such as aluminum (A1) or an aluminum alloy, a silver-based metal such as silver (Ag) or a silver alloy, a copper-based metal such as copper (Cu) or a copper alloy, molybdenum-based metal such as molybdenum (Mo) or molybdenum alloy, chromium (Cr), tantalum (Ta), neodymium (Nd), and titanium (Ti). The second gate electrode 152 may have a multilayer structure including at least two conductive layers each having different physical properties. The second gate electrode 152 may be made of the same material as the first gate electrode 151 or may be made of a different material with the first gate electrode 151.

Referring to FIGS. 1A to 1C, the first gate electrode 151 and the second gate electrode 152 are spaced apart from each other with the active layer 130 therebetween. Although not shown in FIGS. 1A to 1C, the first gate electrode 151 and the second gate electrode 152 may be connected to each other through a contact hole, which is formed in an outer area of the active layer 130.

According to an embodiment of the present disclosure, a same voltage may be applied to the first gate electrode 151 and the second gate electrode 152. The voltage applied to the first gate electrode 151 and the second gate electrode 152 may be referred to as a gate voltage.

According to an embodiment of the present disclosure, the active layer 130 is disposed between the first gate electrode 151 and the second gate electrode 152, and the channel portion 130n may be defined by the first gate electrode 151 and the second gate electrode 152.

Referring to FIGS. 1B and 1C, an interlayer insulating film 160 may be disposed on the second gate electrode 152. The interlayer insulating film 160 may be made of an organic or inorganic insulating material. The interlayer insulating film 160 may be a composite film of an organic film and an inorganic film.

The thin film transistor 100 according to an embodiment of the present disclosure may include a source electrode 171 and a drain electrode 172 disposed on the interlayer insulating film 160. However, the embodiment of the present disclosure is not limited thereto, and the source electrode 171 and the drain electrode 172 may be interchanged. In addition, the first connection portion 130a and the second connection portion 130b may serve as a source electrode and a drain electrode, respectively.

Referring to FIGS. 1A and 1B, the source electrode 171 and the drain electrode 172 may be connected to the active layer 130 through contact holes CH1 and CH2, respectively. In detail, the source electrode 171 may contact the first connection portion 130a through a contact hole CH1. The drain electrode 172 may be spaced apart from the source electrode 171 and may contact the second connection portion 130b through a contact hole CH2.

Hereinafter, the channel portion 130n and the gate electrodes 151 and 152 of the thin film transistor 100 will be described in more detail.

As described above, the channel portion 130n includes a first channel portion CN1 overlapping the first gate electrode 151 and a second channel portion CN2 overlapping the second gate electrode 152.

According to an embodiment of the present disclosure, the first gate electrode 151 and the second gate electrode 152 do not overlap each other, in a plan view. Therefore, according to an embodiment of the present disclosure, the first channel portion CN1 and the second channel portion CN2 do not overlap each other.

In addition, according to an embodiment of the present disclosure, the first channel portion CN1 does not overlap the second gate electrode 152, and the second channel portion CN2 does not overlap the first gate electrode 151.

Referring to FIG. 1A, the first channel portion CN1 and the second channel portion CN2 each extend from the first connection portion 130a to the second connection portion 130b. The first channel portion CN1 and the second channel portion CN2 may be arranged side by side from the first connection portion 130a to the second connection portion 130b, and may be spaced apart each other at a predetermined interval.

According to an embodiment of the present disclosure, the first gate insulating layer 141 may have a thickness 2 to 3 times a thickness of the second gate insulating layer 142. Referring to FIGS. 1B and 1C, the first gate insulating layer 141 serves to insulate and separate the first gate electrode 151 and the active layer 130, and the first gate insulating layer 141 is disposed between the base substrate 110 and active layer 130 to protect the active layer 130. For example, the first gate insulating layer 141 serves as a protective layer for the active layer 130 by blocking moisture or oxygen penetrating from the base substrate 110.

The second gate insulating layer 142 serves to insulate the active layer 130 and the second gate electrode 152 and protects the active layer 130.

According to an embodiment of the present disclosure, since the first gate insulating layer 141 has a function to protect the active layer 130 from oxygen or moisture penetrating from the base substrate 110, the first gate insulating layer 141 may be designed so that the thickness t1 of the first gate insulating layer 141 is greater than the thickness t2 of the second gate insulating layer 142.

For example, the thickness t1 of the first gate insulating layer 141 may be 2 to 3 times greater than the thickness t2 of the second gate insulating layer 142. The thickness of the gate insulating layers 141 and 142 may be defined by the distance between the gate electrodes 151 and 152 and the active layer 130.

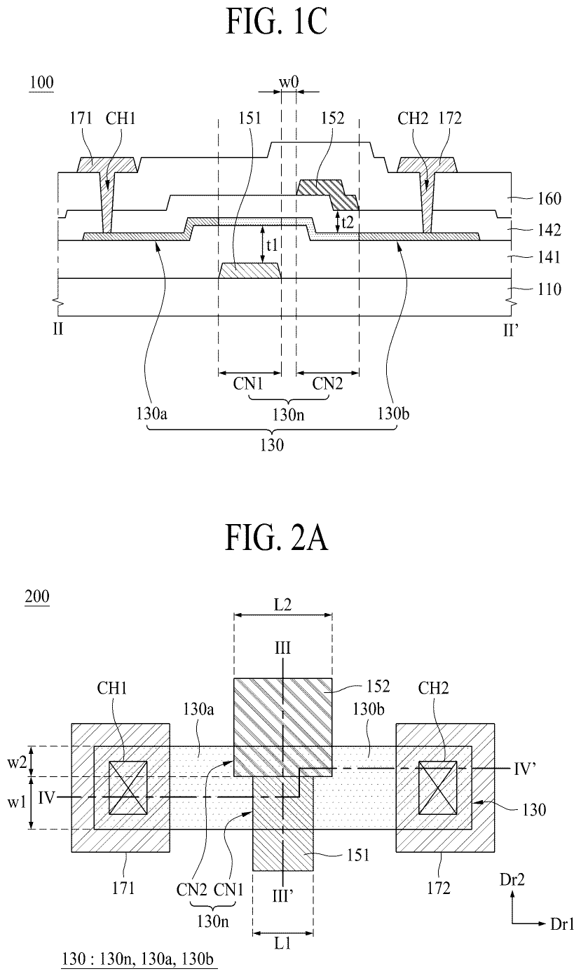

In detail, based on cross-sectional views of FIGS. 1B, 1C, 2B, and 2C, the thickness t1 of the first gate insulating layer 141 may be defined as a distance between the upper surface of the first gate electrode 151 and the lower surface of the active layer 130. In addition, the thickness t2 of the second gate insulating layer 142 may be defined as a distance between the upper surface of the active layer 130 and the lower surface of the second gate electrode 152. In this case, based on the cross-sectional view, a surface at the upper side is defined as the upper surface, and a surface at the lower side is defined as the lower surface.

According to an embodiment of the present disclosure, a distance between the first channel portion CN1 and the first gate electrode 151 is greater than a distance between the second channel portion CN2 and the second gate electrode 152. Accordingly, a relatively weaker electric field is applied to the first channel portion CN1 than an electric filed applied to the second channel portion CN2. And, as a result, the s-factor (subthreshold swing; SS) of the thin film transistor 100 may be increased by the first channel portion CN1.

In addition, according to an embodiment of the present disclosure, because the first gate insulating layer 141 should serve as a buffer layer to block oxygen (O2) or moisture penetrating from the base substrate 110, the first gate insulating layer 141 may be made of an oxide such as silicon oxide. Since silicon oxide has a relatively low dielectric constant, a relatively weak electric field may be applied to the first channel portion CN1, and thus, the s-factor of the thin film transistor 100 may be increased by the first channel portion CN1.

Meanwhile, when the first gate electrode 151 and the second gate electrode 152 overlap, both the electric field by the first gate electrode 151 and the electric field by the second gate electrode 152 are applied to the first channel portion CN1, which has shorter length than the second channel portion CN2. In detail, there is a part in the first channel portion CN1 where both of the electric fields are applied, and the current change in the first channel portion CN1 may increase in the threshold voltage section. As a result, the effect of increasing the s-factor by the first channel portion CN1 may decrease, and the s-factor of the thin film transistor 100 may decrease. Therefore, according to an embodiment of the present disclosure, in order to prevent a decrease in s-factor, the first gate electrode 151 and the second gate electrode 152 are designed not to overlap each other.

In detail, according to an embodiment of the present disclosure, the first gate electrode 151 and the second gate electrode 152 may be spaced apart from each other without overlapping, in a plan view. An arranging state in which the first gate electrode 151 and the second gate electrode 152 are spaced apart is shown in FIG. 1A, in a plan view. As the first gate electrode 151 and the second gate electrode 152 are spaced apart, the first channel portion CN1 and the second channel portion CN2 may be arranged to be spaced apart from each other.

However, an embodiment of the present disclosure is not limited thereto, and the edges of the first gate electrode 151 and the second gate electrode 152 may be disposed in contact with each other in a plan view (see FIG. 2A), and accordingly, the edges of the first channel portion CN1 and the second channel portion CN2 may be disposed to contact each other in a plan view (see FIG. 2A). If a completely precise process without error is possible, the edges of the first channel portion CN1 and the second channel portion CN2 may be designed to be in contact with each other in a plan view.

According to an embodiment of the present disclosure, the separation distance between the first gate electrode 151 and the second gate electrode 152 in a plan view may be 0 or more and 1 μm or less. Accordingly, the separation distance w0 between the first channel portion CN1 and the second channel portion CN2 may be 0 or more and 1 μm or less. The state that “the separation distance w0 between the first channel portion CN1 and the second channel portion CN2 is 0 μm” means that the edges of the first channel portion CN1 and the second channel portion CN2 are in contact with each other in a plan view.

According to an embodiment of the present disclosure, the separation distance between the first gate electrode 151 and the second gate electrode 152 in a plan view may be greater than 0 μm, and less than or equal to 1 μm. In addition, a separation distance between the first gate electrode 151 and the second gate electrode 152 in a plan view may be in a range of 0.1 μm to 1 μm. Accordingly, the separation distance w0 between the first channel portion CN1 and the second channel portion CN2 may be greater than 0 μm and less than or equal to 1 μm, and in more detail, may be in the range of 0.1 μm to 1 μm.

Referring to FIGS. 1A and 1B, a width of the first channel portion CN1 is w1 and a width of the second channel portion CN2 is w2. When the separation distance w0 between the first channel portion CN1 and the second channel portion CN2 exceeds 1 μm, the overall width (w1+w2+w0) of the active layer 130 increases. And accordingly, as the size of the thin film transistor 100 increases, difficulties may arise in miniaturizing the device. In addition, when the separation distance w0 between the first channel portion CN1 and the second channel portion CN2 exceeds 1 μm, the effective channel width (w1+w2) of the thin film transistor 100 may be reduced to negatively affect the driving current of the thin film transistor 100, and accordingly, the on-current of the thin film transistor 100 may be reduced. According to an embodiment of the present disclosure, the effective channel width of the thin film transistor 100 is defined as a sum (w1+w2) of the width w1 of the first channel portion CN1 and the width w2 of the second channel portion CN2.

In detail, in a device to which the thin film transistor 100 is applied, for example, in a display apparatus, an area that the thin film transistor 100 can occupy is limited, and the entire width (w1+w2+w0) of the active layer 130 is also limited. In a condition where the total width (w1+w2+w0) of the active layer 130 is limited, if the separation distance w0 between the first channel portion CN1 and the second channel portion CN2 exceeds 1 μm, the effective channel width (w1+w2) determined by the width w1 of the first channel portion CN1 and the width w2 of the second channel portion CN2 is reduced by more than 1 μm. When the effective channel width (w1+w2) of the thin film transistor 100 is reduced, the area where current can flow in the thin film transistor 100 is reduced, and the on-current of the thin film transistor 100 decreases.

As described above, in order to prevent an increase in device size and a decrease in the width (w1+w2) of the effective channel portion 130n of the thin film transistor 100, the separation distance w0 between the first channel portion CN1 and the second channel portion CN2 can be set to 1 μm or less. However, an embodiment of the present disclosure is not limited thereto, and if there is no limitation in the size of the thin film transistor 100, the separation distance w0 between the first channel portion CN1 and the second channel portion CN2 may exceed 1 μm.

According to an embodiment of the present disclosure, the first channel portion CN1 and the second channel portion CN2 are spaced apart along the direction Dr2 perpendicular to the first direction Dr1, which is extending from the first connection portion 130a to the second connection portion 130b. According to an embodiment of the present disclosure, the separation distance w0 between the first channel portion CN1 and the second channel portion CN2 is measured along a second direction Dr2, which is perpendicular to the first direction Dr1 extending from the first connection portion 130a to the second connection portion 130b.

Referring to FIG. 1A, the first direction Dr1, which is extending from the first connection portion 130a to the second connection portion 130b, may be referred to as a “longitudinal direction” of the channel. In addition, the second direction Dr2, which is perpendicular to the first direction Dr1, may be referred to as a “width direction” of the channel. According to an embodiment of the present disclosure, a distance between both ends of the channel portion 130n measured along the first direction Dr1 extending from the first connection portion 130a to the second connection portion 130b is defined as “channel length,” and a distance between both ends of the channel portion 130n measured along the second direction Dr2 perpendicular to the first direction Dr1 is defined as “channel width.”

In addition, according to an embodiment of the present disclosure, the width w1 of the first channel portion CN1 is defined by the first gate electrode 151, and the width w2 of the second channel portion CN2 is defined by the second gate electrode 152. In detail, a width of the area overlapping the first gate electrode 151 in the channel portion 130n is defined as the width w1 of the first channel portion CN1. In addition, a width of the area overlapping the second gate electrode 152 is defined as the width w2 of the second channel portion CN2.

According to an embodiment of the present disclosure, the width w1 of the first channel portion CN1 and the width w2 of the second channel portion CN2 may be designed differently depending on the purpose of the thin film transistor 100. According to an embodiment of the present disclosure, the s-factor of the thin film transistor 100 is mainly determined by the first channel portion CN1, and the on-current of the thin film transistor 100 is mainly determined by the second channel portion CN2. Depending on the s-factor and on-current required for the thin film transistor 100, the width w1 of the first channel portion CN1 and the width w2 of the second channel portion CN2 can be determined.

According to an embodiment of the present disclosure, as illustrated in FIG. 1A, the width of the first gate electrode 151 is larger than the width of the second gate electrode 152 in an area overlapping the active layer 130. Accordingly, the width w1 of the first channel portion CN1 is larger than the width w2 of the second channel portion CN2 (w1>w2).

In the width of the entire channel portion 130n, when the width w1 of the first channel portion CN1 is less than 20% and the width w2 of the second channel portion CN2 exceeds 80%, the s-factor of the thin film transistor 100 may not be large enough. On the other hand, when the width w1 of the first channel portion CN1 exceeds 80% and the width w2 of the second channel portion CN2 is less than 20% in the width of the entire channel portion 130n, on-current of the thin film transistor 100 may be reduced. Considering this correlation, according to an embodiment of the present disclosure, a ratio of the width w1 of the first channel portion CN1 and the width w2 of the second channel portion CN2 may be designed in a range of 8:2 to 2:8.

In more detail, according to an embodiment of the present disclosure, the ratio of the width w1 of the first channel portion CN1 and the width w2 of the second channel portion CN2 may be in a range of 3:7 to 7:3. In addition, the ratio of the width w1 of the first channel portion CN1 and the width w2 of the second channel portion CN2 may be in a range of 4:6 to 6:4, and in a range of 4.5:5.5 to 5.5:4.5.

The length L1 of the first channel portion CN1 and the length L2 of the second channel portion CN2 are designed so that the thin film transistor 100 can effectively have switching characteristics. It is advantageous to miniaturize the device if the lengths L1, L2 of the first channel portion CN1 and the second channel portion CN2 are short.

According to an embodiment of the present disclosure, the ratio (L1:L2) of the length L1 of the first channel portion CN1 and the length L2 of the second channel portion CN2 may be in a range of 1:2 to 2:1.

If the length L1 of the first channel portion CN1 is less than ½ of the length L2 of the second channel portion CN2, there may be difficulties in securing the effective channel length of the first channel portion CN1. For example, when a maximum channel length of the thin film transistor 100, which is used as a driving transistor, is designed to be 6 μm, the length L2 of the second channel portion CN2 may be 6 μm, and the length L1 of the first channel portion CN1 may be 3 μm at most. However, if the length L1 of the first channel portion CN1 is 3 μm or less, there may be difficulty in securing an effective channel length. On the other hand, when the length L1 of the first channel portion CN1 exceeds twice the length L2 of the second channel portion CN2, there may be difficulty in minimizing the thin film transistor 100 due to an increase in the channel length.

In opposition, if the length L2 of the second channel portion CN2 is less than ½ the length L1 of the first channel portion CN1, there may be difficulties in securing the effective channel length of the second channel portion CN2. In addition, when the length L2 of the second channel portion CN2 exceeds twice the length L1 of the first channel portion CN1, there may be difficulty in minimizing the thin film transistor 100 due to an increase in the channel length.

Referring to FIG. 1A, the width w1 of the first channel portion CN1 may be larger than the width w2 of the second channel portion CN2 (w1>w2). When the width w1 of the first channel portion CN1, which determines the s-factor of the thin film transistor 100, is greater than the width w2 of the second channel portion CN2, the thin film transistor 100 may have advantages in increasing the s-factor.

In addition, referring to FIG. 1A, the length L1 of the first channel portion CN1 may be smaller than the length L2 of the second channel portion CN2 (L1<L2). By reducing the length L1 of the first channel portion CN1 to which a relatively weak electric field is applied, the current flowing through the thin film transistor 100 can be prevented from decreasing. In addition, by making the length L2 of the second channel portion CN2 to which a relatively strong electric field is applied relatively larger than the length L1 of the first channel portion CN1, the thin film transistor 100 can allow a stable current to flow in an on-current state.

FIG. 2A is a plan view of a thin film transistor 200 according to another embodiment of the present disclosure, FIG. 2B is a cross-sectional view along a line III-III′ of FIG. 2A, and FIG. 2C is a cross-sectional view along a line IV-IV′ of FIG. 2A. Hereinafter, in order to avoid redundancy, descriptions for components which are already described may be omitted.

Referring to FIGS. 2A, 2B, and 2C, in a plan view, the edges of the first channel portion CN1 and the second channel portion CN2 may be disposed to contact each other. If a precise process without error is possible, the edges of the first channel portion CN1 and the second channel portion CN2 may be designed to contact each other in a plan view. In the structure of the thin film transistor 200 illustrated in FIGS. 2A, 2B, and 2C, the separation distance w0 between the first channel portion CN1 and the second channel portion CN2 may be 0 μm.

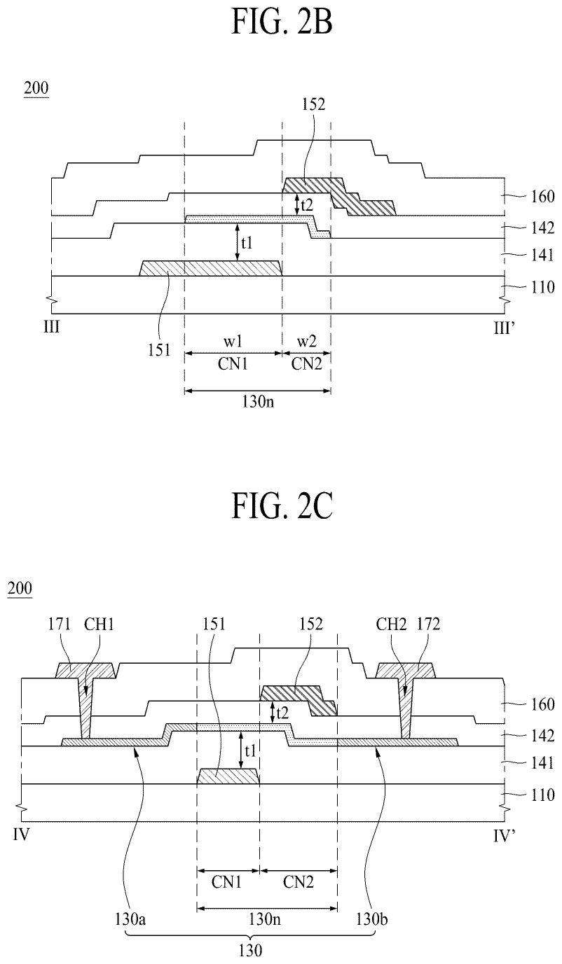

FIGS. 3A and 3B are cross-sectional views of a thin film transistor 300 according to another embodiment of the present disclosure, respectively. In detail, FIG. 3A corresponds to a cross-sectional view taken along I-I′ of FIG. 1A, and FIG. 3B corresponds to a cross-sectional view taken along II-II′ of FIG. 1A.

Referring to FIGS. 3A and 3B, the second gate insulating layer 142 may have a patterned structure. Even if the second gate insulating layer 142 is patterned, the second gate insulating layer 142 is designed to cover the entire upper surface of the channel portion 130n. Referring to FIGS. 3A and 3B, the second gate insulating layer 142 covers at least the portion of the active layer 130 that overlaps the first gate electrode 151 and the portion of the active layer 130 that overlaps the second gate electrode 152.

In the process of patterning the second gate insulating layer 142, the active layer 130 may be selectively conductorized to form the first connection portion 130a and the second connection portion 130b.

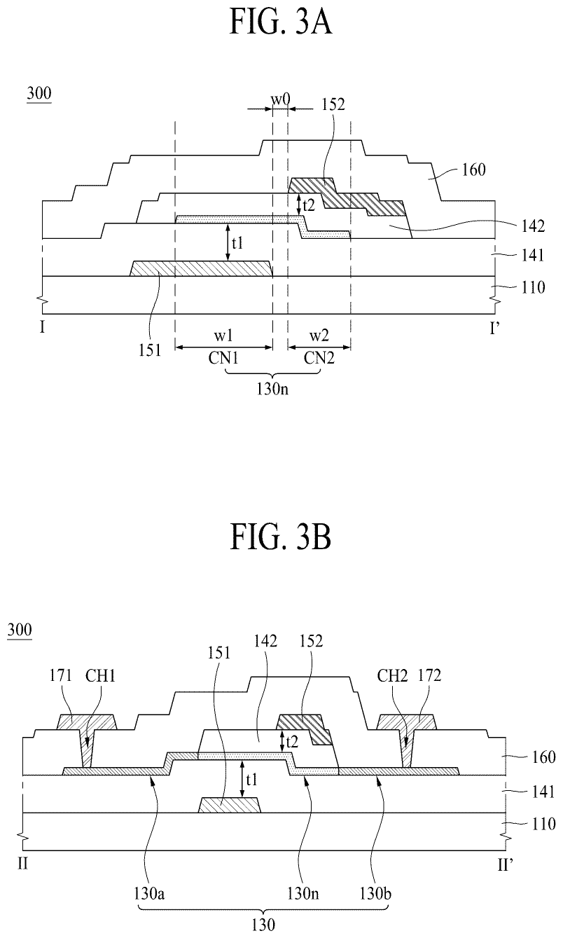

FIG. 4 is a cross-sectional view of a thin film transistor 400 according to another embodiment of the present disclosure.

Referring to FIG. 4, the active layer 130 may have a multilayer structure. According to an embodiment of the present disclosure, the active layer 130 may include a first oxide semiconductor layer 131, and a second oxide semiconductor layer 132 on the first oxide semiconductor layer 131. The first oxide semiconductor layer 131 and the second oxide semiconductor layer 132 may be made of different oxide semiconductor materials.

For example, the first oxide semiconductor layer 131 may include a gallium (Ga)-based oxide semiconductor material with excellent stability. The first oxide semiconductor layer 131 containing a gallium (Ga)-based oxide semiconductor material may have a stable layer structure. The second oxide semiconductor layer 132 may be made of an oxide semiconductor material with excellent mobility. In this case, the main channel may be formed in the second oxide semiconductor layer 132. However, an embodiment of the present disclosure is not limited thereto, and the first oxide semiconductor layer 131 may have excellent mobility and the second oxide semiconductor layer 132 may have a stable layer structure.

According to an embodiment of the present disclosure, the on-current of the thin film transistor 400 is mainly determined by the second channel portion CN2. The second channel portion CN2 is an area of the active layer 130 that overlaps the second gate electrode 152, and is driven by the voltage applied to the second gate electrode 152. In the thin film transistor 400 illustrated in FIG. 4, since the second oxide semiconductor layer 132 is disposed closer to the second gate electrode 152 than the first oxide semiconductor layer 131, it can be said that the driving characteristics of the second channel portion CN2 may be determined by the second oxide semiconductor layer 132. And therefore, it can be said that the on-current characteristics of the thin film transistor 400 are mainly affected by the second oxide semiconductor layer 132. The second oxide semiconductor layer 132, which determines the on-current of the thin film transistor 400 illustrated in FIG. 4, may have greater mobility than the first oxide semiconductor layer 131. In detail, in order to improve the on-current characteristics of the thin film transistor 400, the second oxide semiconductor layer 132 disposed close to the second gate electrode 152 may have a mobility greater than a mobility of the first oxide semiconductor layer 131.

For the stability of the channel portion 130n, the first oxide semiconductor layer 131 contacting the first gate insulating layer 141 may be made of an oxide semiconductor material with excellent stability. Generally, oxide semiconductor materials with excellent stability contain a relatively large amount of gallium (Ga) and have relatively low mobility. Therefore, for the structural stability of the thin film transistor 400 and the stability of the channel portion 130n, the first oxide semiconductor layer 131 may have a lower mobility than a mobility of the second oxide semiconductor layer 132.

FIG. 5 is a cross-sectional view of a thin film transistor 500 according to another embodiment of the present disclosure.

Referring to FIG. 5, a light shielding layer 111 may be disposed on the base substrate 110. The light shielding layer 111 may be made of a material with light blocking properties. The light shielding layer 111 blocks light incident from the outside and protects the active layer 130.

Referring to FIG. 5, a buffer layer 120 may be disposed on the light shielding layer 111. The buffer layer 120 may include at least one of silicon oxide, silicon nitride, and metal-based oxide. The buffer layer 120 protects the active layer 130. In addition, a surface of the upper portion over the base substrate 110 on which the light shielding layer 111 is disposed can be made flat by the buffer layer 120.

Referring to FIG. 5, the first gate electrode 151 may be disposed on the buffer layer 120.

The light shielding layer 111 may be connected to the source electrode 171. By connecting the light shielding layer 111 to the source electrode 171, a certain voltage can be applied to the light shielding layer 111. Accordingly, the light shielding layer 111 can be prevented from being left in a floating state.

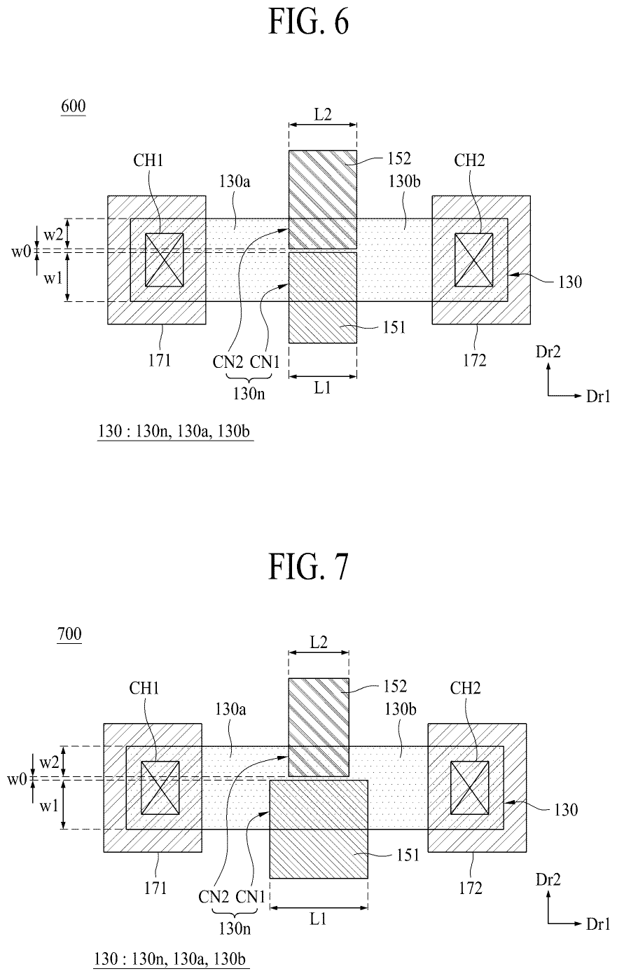

FIG. 6 is a plan view of a thin film transistor 600 according to another embodiment of the present disclosure. FIG. 6 illustrates one of the embodiments in which the sizes of the first channel portion CN1, the second channel portion CN2, the first gate electrode 151, and the second gate electrode 152 are changed as needed.

Referring to FIG. 6, the first channel portion CN1 and the second channel portion CN2 may have the same length (L1=L2). In detail, in another embodiment of the present disclosure, the length L1 of the first channel portion CN1 and the length L2 of the second channel portion CN2 of the thin film transistor 600 may be the same. The embodiment, in which the length L1 of the first channel portion CN1 and the length L2 of the second channel portion CN2 are the same, may serve as a reference for comparing changes in the performance of thin film transistors depending on changes in the length L1 and in the length L2.

In addition, in FIG. 6, the width w1 of the first channel portion CN1 is larger than the width w2 of the second channel portion CN2 (w1>w2). The thin film transistor 600 of FIG. 6 may have a large s-factor.

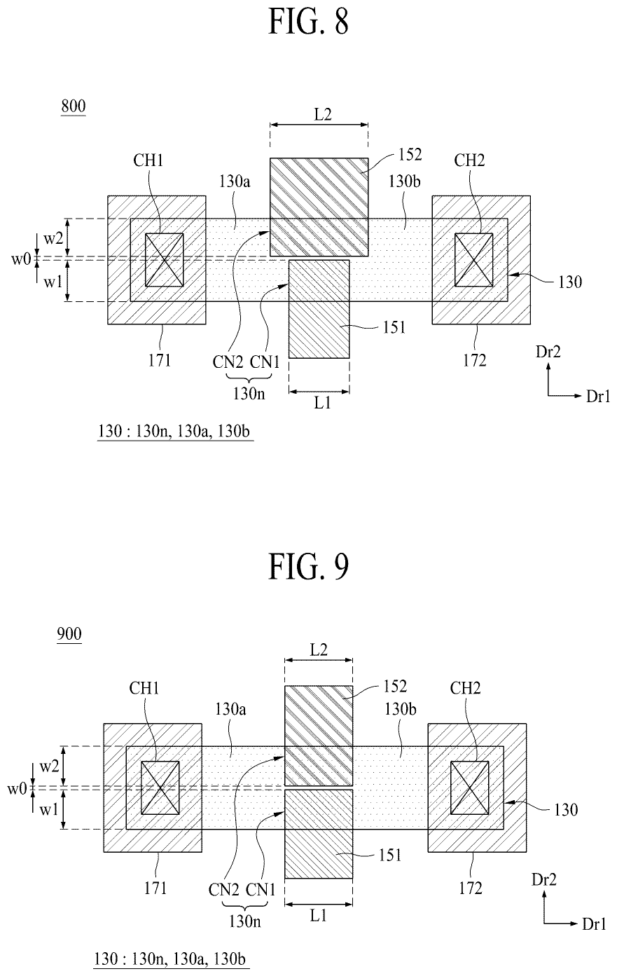

FIG. 7 is a plan view of a thin film transistor 700 according to another embodiment of the present disclosure. FIG. 7 illustrates one of embodiments in which the sizes of the first channel portion CN1, the second channel portion CN2, the first gate electrode 151, and the second gate electrode 152 are changed, as needed.

Referring to FIG. 7, the length L1 of the first channel portion CN1 may be larger than the length L2 of the second channel portion CN2 (L1>L2). In addition, in FIG. 7, the width w1 of the first channel portion CN1 is larger than the width w2 of the second channel portion CN2 (w1>w2).

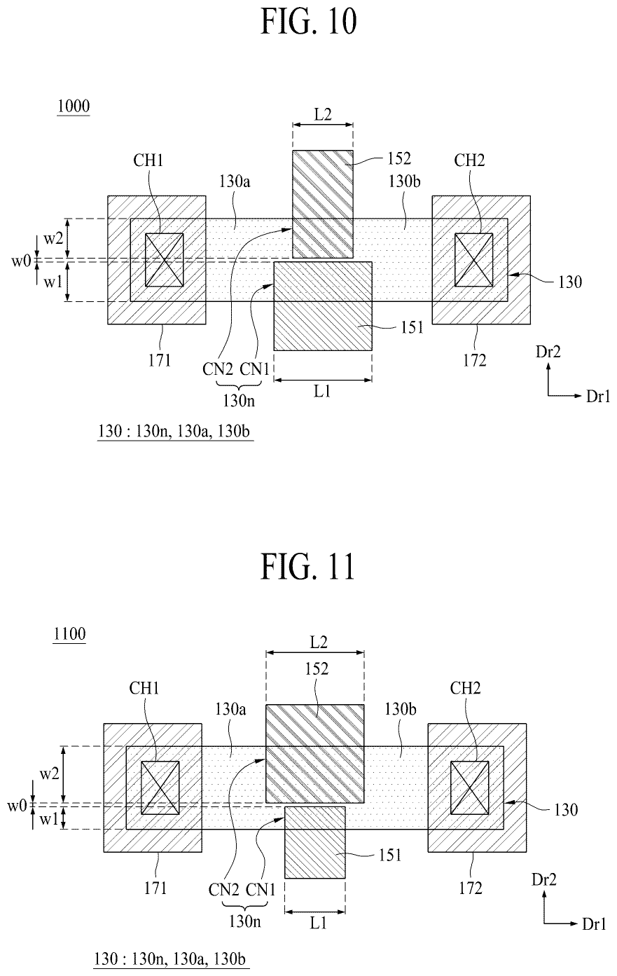

FIG. 8 is a plan view 800 of a thin film transistor according to another embodiment of the present disclosure.

Referring to FIG. 8, the first channel portion CN1 and the second channel portion CN2 may have the same width (w1=w2). In detail, in another embodiment of the present disclosure, the width w1 of the first channel portion CN1 and the width w2 of the second channel portion CN2 of the thin film transistor 800 may be the same. In addition, referring to FIG. 8, the length L1 of the first channel portion CN1 may be smaller than the length L2 of the second channel portion CN2 (L1<L2).

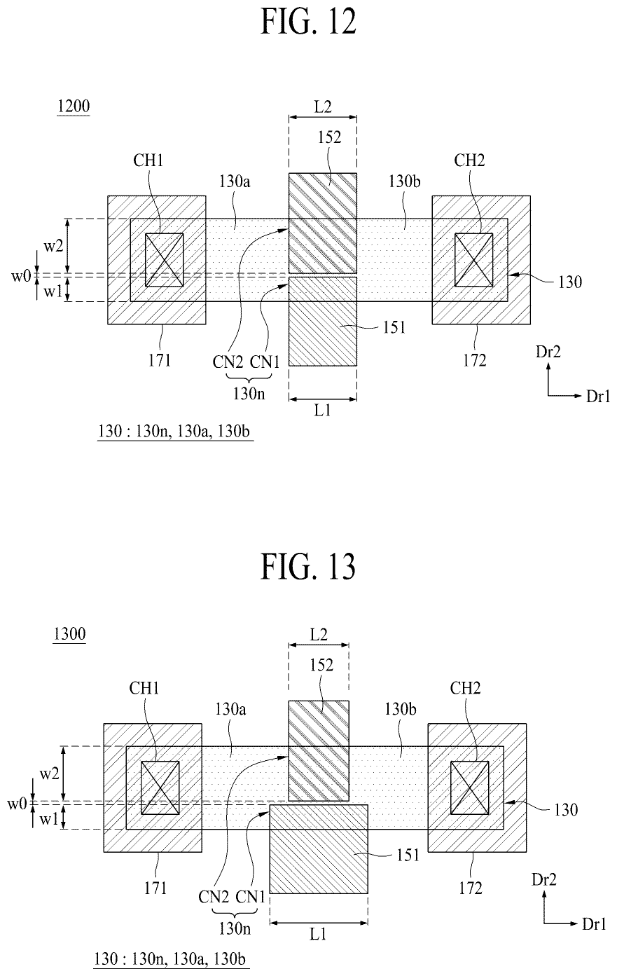

FIG. 9 is a plan view of a thin film transistor 900 according to another embodiment of the present disclosure.

Referring to FIG. 9, the first channel portion CN1 and the second channel portion CN2 may have the same width (w1=w2). In addition, the length L1 of the first channel portion CN1 and the length L2 of the second channel portion CN2 may be the same (L1=L2).

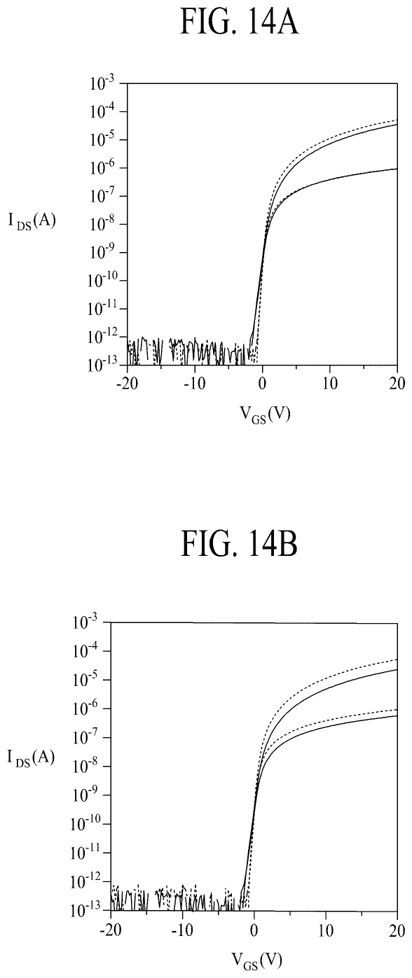

FIG. 10 is a plan view of a thin film transistor 1000 according to another embodiment of the present disclosure.

Referring to FIG. 10, the first channel portion CN1 and the second channel portion CN2 may have the same width (w1=w2). In addition, the length L1 of the first channel portion CN1 may be larger than the length L2 of the second channel portion CN2 (L1>L2).

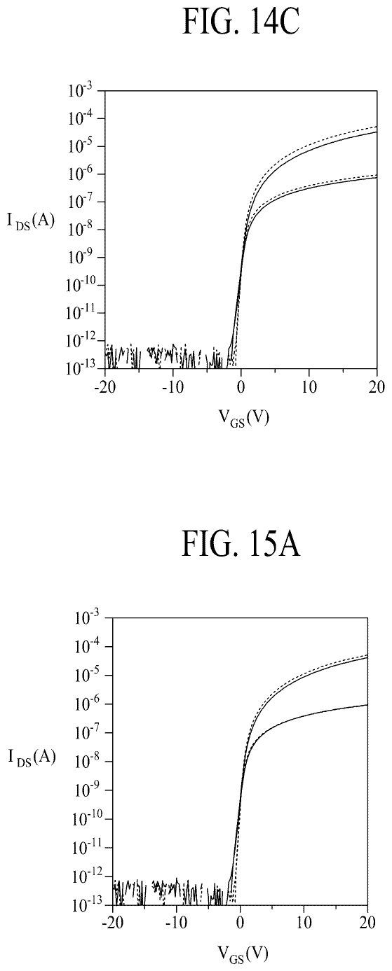

FIG. 11 is a plan view of a thin film transistor 1100 according to another embodiment of the present disclosure.

Referring to FIG. 11, the first channel portion CN1 may have a width w1 that is smaller than a width w2 of the second channel portion CN2 (w1<w2). In detail, in another embodiment of the present disclosure, the width w1 of the first channel portion CN1 of the thin film transistor 1100 may be smaller than a width w2 of the second channel portion CN2 (w1<w2). In addition, referring to FIG. 11, the length L1 of the first channel portion CN1 may be smaller than the length L2 of the second channel portion CN2 (L1<L2).

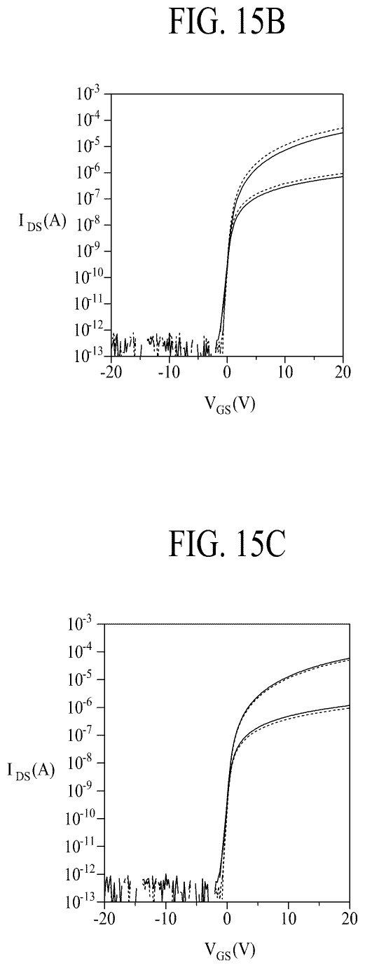

FIG. 12 is a plan view of a thin film transistor 1200 according to another embodiment of the present disclosure.

Referring to FIG. 12, the first channel portion CN1 may have a width w1 smaller than a width w2 of the second channel portion CN2 (w1<w2). In addition, referring to FIG. 12, the length L1 of the first channel portion CN1 may be equal to the length L2 of the second channel portion CN2 (L1=L2).

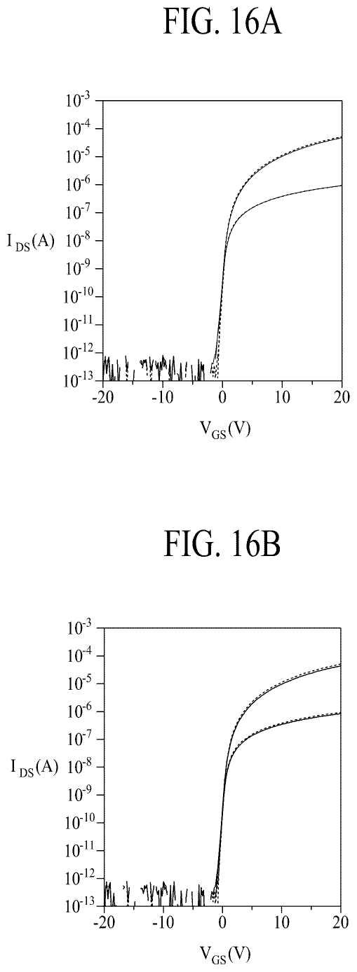

FIG. 13 is a plan view of a thin film transistor 1300 according to another embodiment of the present disclosure.

Referring to FIG. 13, the first channel portion CN1 may have a width w1 smaller than a width w2 of the second channel portion CN2 (w1<w2). In addition, referring to FIG. 13, the length L1 of the first channel portion CN1 may be larger than the length L2 of the second channel portion CN2 (L1>L2).

As described above, according to an embodiment of the present disclosure, the thickness t2 of the second gate insulating layer 142, which mainly serves to insulate the active layer 130 and the second gate electrode 152, is smaller than the thickness t1 of the first gate insulating layer 141, which serves as a protecting layer to protect the active layer 130 by blocking moisture or oxygen penetrating from the base substrate 110 (t1>t2). According to an embodiment of the present disclosure, the second channel portion CN2, which is affected by the second gate electrode 152 disposed on the second gate insulating layer 142 having a small thickness t2, plays a main role in determining the on-current of the thin film transistor 1300.

In the thin film transistor 1300 according to another embodiment of the present disclosure, among the total width of the channel portion 130n, the portion occupied by the second channel portion CN2 that determines the on-current is large, and the second channel portion CN2 is a short channel having a short length, so that the thin film transistor 1300 can have excellent on-current characteristics.

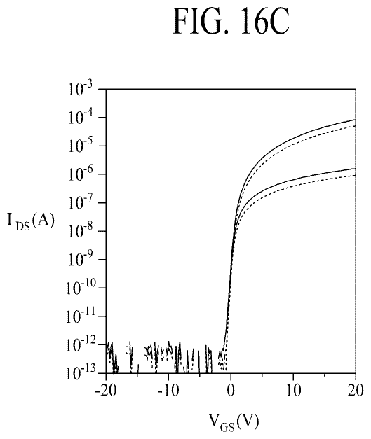

FIGS. 14A, 14B, and 14C are threshold voltage (Vth) graphs of thin film transistors 100, 600, and 700, respectively.

In detail, FIGS. 14A, 14B, and 14C illustrate threshold voltage graphs for the thin film transistors 100, 600, 700, in which the width w1 of the first channel portion CN1 is larger than the width w2 of the second channel portion CN2 (w1>w2).

The threshold voltage Vth graph for thin film transistor illustrates the relation between the drain-source current I_{DS} to the gate voltage V_{GS}.

In the graphs illustrated in FIGS. 14A, 14B, and 14C, the section in which the current rapidly increases before the thin film transistor is completely turned on may be referred to as a threshold voltage Vth section. According to an embodiment of the present disclosure, the s-factor is defined as the reciprocal of the slope of the drain-source current I_{DS} graph with respect to the gate voltage V_{GS} in the threshold voltage Vth section. If the slope of the graph is steep, the s-factor is small, and if the slope of the graph is small, the s-factor is large. When the s-factor is large, the rate of change of drain-source current I_{DS} to a change in gate voltage in the threshold voltage Vth region is small.

When the s-factor is large, because the rate of change of the drain-source current I_{DS} with respect to the gate voltage V_{GS} is small in the threshold voltage Vth section, it is easy to control the magnitude of the drain-source current I_{DS} by adjusting the gate voltage V_{GS}. In a display apparatus driven by current, for example, an organic light emitting display apparatus, the gray scale of the pixel can be controlled by adjusting the magnitude of the drain-source current I_{DS} of the driving thin film transistor, and the magnitude of the drain-source current I_{DS} of the driving thin film transistor can be determined by the gate voltage. Therefore, in an organic light emitting display apparatus, the larger the s-factor of the driving thin film transistor (Driving TR), the easier it is to adjust the gray scale of the pixel.

In the thin film transistors measured in FIGS. 14A, 14B, and 14C, the thickness t1 of the first gate insulating layer 141 is 400 nm, and the thickness t2 of the second gate insulating layer 142 is 150 nm. Hereinafter, for other thin film transistors to be measured, the thickness t1 of the first gate insulating layer 141 is 400 nm, and the thickness t2 of the second gate insulating layer 142 is 150 nm.

In FIGS. 14A, 14B, and 14C, the dotted lines are threshold voltage graphs of the thin film transistors according to comparative examples. Each of the thin film transistor according to the comparative examples has the structure according to FIGS. 1A, 6 and 7, respectively, except the gate electrode. In each of the thin film transistor according to the comparative examples, there is only second gate electrode 152 as gate electrode, which extends in the width direction Dr2 of the active layer 130, so that the second gate electrode 152 overlaps the entire channel portion 130n. The same applies to the graph below.

In FIGS. 14A, 14B, and 14C, the solid lines indicate the threshold voltage graphs for the thin film transistor 100 (w1>w2, L1<L2) of FIG. 1A, the thin film transistor 600 (w1>w2, L1=L2) of FIG. 6, and the thin film transistor 700 (w1>w2, L1>L2) of FIG. 7, respectively.

Referring to FIGS. 14A, 14B, and 14C, it can be seen that the thin film transistors 100, 600, and 700 according to embodiments of the present disclosure have excellent s-factor characteristics compared to the thin film transistors of the comparative examples.

In detail, referring to FIG. 14A, the thin film transistor 100 of FIG. 1A according to an embodiment of the present disclosure may have an s-factor of 0.45. Referring to FIG. 14B, the thin film transistor 600 of FIG. 6 according to another embodiment of the present disclosure may have an s-factor of 0.42. In addition, referring to FIG. 14C, the thin film transistor 700 of FIG. 7 according to another embodiment of the present disclosure may have an s-factor of 0.38.

As described above, each of the thin film transistors 100, 600, and 700 according to embodiments of the present disclosure has a large s-factor and can be applied as driving thin film transistor (Driving TR) of an organic light emitting display apparatus.

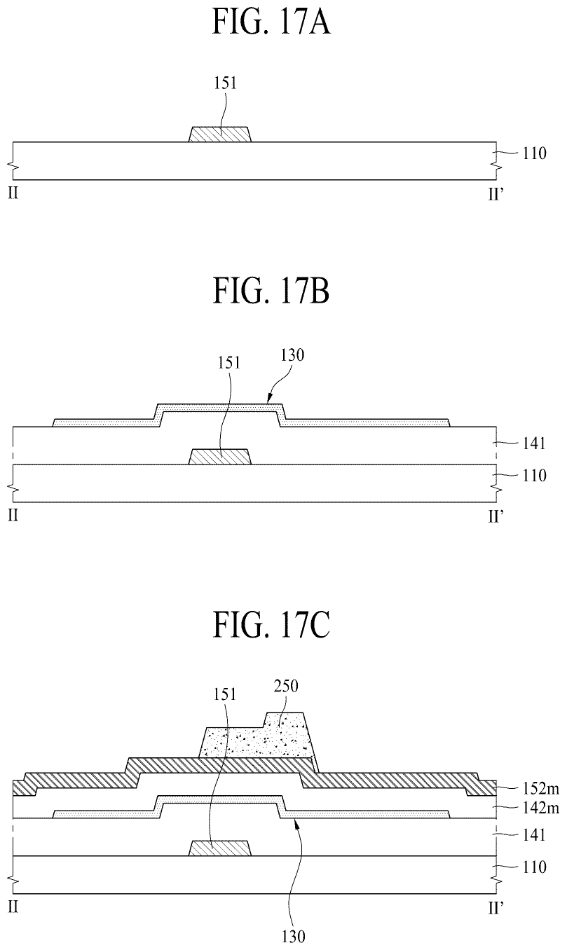

FIGS. 15A, 15B, and 15C are threshold voltage graphs of thin film transistors 800, 900, and 1000, respectively.

In detail, FIGS. 15A, 15B, and 15C illustrate threshold voltage graphs for the thin film transistors 800, 900, 1000, in which the width w1 of the first channel portion CN1 is the same with the width w2 of the second channel portion CN2 (w1=w2).

In FIGS. 15A, 15B, and 15C, the dotted lines are threshold voltage graphs of the thin film transistors according to the comparative examples. The structure of the thin film transistors according to the comparative examples are as described above.

In FIGS. 15A, 15B, and 15C, the solid lines indicate the threshold voltage graphs for the thin film transistor 800 (w1=w2, L1<L2) of FIG. 8, the thin film transistor 900 (w1=w2, L1=L2) of FIG. 9, and the thin film transistor 1000 (w1=w2, L1>L2) of FIG. 10, respectively.

Referring to FIGS. 15A, 15B, and 15C, it can be seen that the thin film transistors 800, 900, and 1000 according to embodiments of the present disclosure have excellent s-factor characteristics compared to the thin film transistors of the comparative examples.

In detail, referring to FIG. 15A, the thin film transistor 800 of FIG. 8 may have an s-factor of 0.38. Referring to FIG. 15B, the thin film transistor 900 of FIG. 9 may have an s-factor of 0.41. In addition, referring to FIG. 15C, the thin film transistor 1000 of FIG. 10 may have an s-factor of 0.32.

As described above, each of the thin film transistors 800, 900, and 1000 according to embodiments of the present disclosure has a large s-factor and can be applied as driving thin film transistor (Driving TR) of an organic light emitting display apparatus.

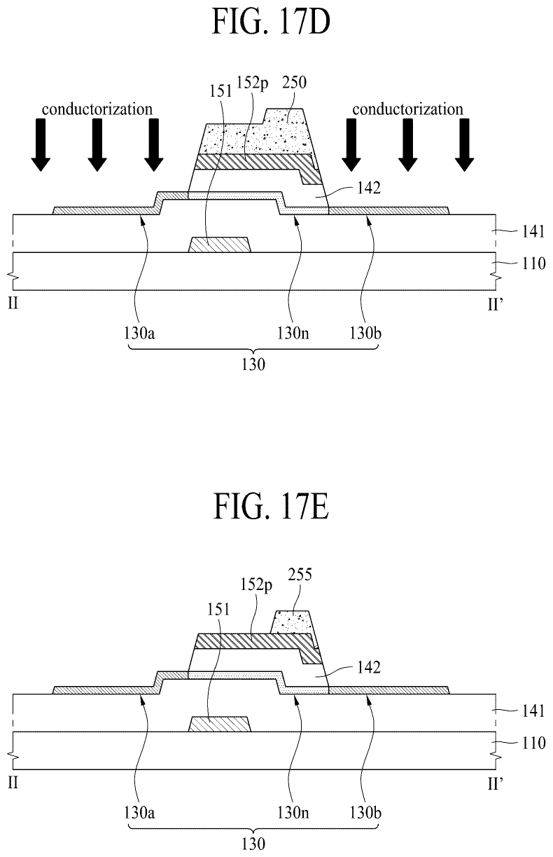

FIGS. 16A, 16B, and 16C are threshold voltage graphs of thin film transistors 1100, 1200, and 1300, respectively.

In detail, FIGS. 16A, 16B, and 16C illustrate threshold voltage graphs for the thin film transistors 1100, 1200, 1300, in which the width w1 of the first channel portion CN1 is smaller than the width w2 of the second channel portion CN2 (w1<w2).

In FIGS. 16A, 16B, and 16C, the dotted lines are threshold voltage graphs of the thin film transistor according to the comparative examples. The structure of the thin film transistors according to the comparative examples are as described above.

In FIGS. 16A, 16B, and 16C, the solid lines indicate the threshold voltage graph for the thin film transistor 1100 (w1<w2, L1<L2) of FIG. 11, the thin film transistor 1200 (w1<w2, L1=L2) of FIG. 12, and the thin film transistor 1300 (w1<w2, L1>L2) of FIG. 13, respectively.

Referring to FIGS. 16A and 16B, it can be seen that the thin film transistors 1100 and 1200 according to embodiments of the present disclosure have excellent s-factor characteristics compared to the thin film transistors of the comparative examples. In detail, referring to FIG. 16A, the thin film transistor 1100 of FIG. 11 may have an s-factor of 0.32. Referring to FIG. 16B, the thin film transistor 1200 of FIG. 12 may have an s-factor of 0.32.

As described above, the thin film transistors 1100 and 1200 according to embodiments of the present disclosure have large s-factors, and thus can be applied as driving thin film transistors (Driving TR) of an organic light emitting display apparatus.

In addition, referring to FIG. 16C, it can be seen that the thin film transistor 1300 of FIG. 13 according to an embodiment of the present disclosure has excellent on-current characteristics compared to the thin film transistor of the comparative example. In detail, referring to FIG. 16C, the thin film transistor 1300 of FIG. 13 may have an on-current of 5.3 μA. According to an embodiment of the present disclosure, the on-current may be defined as the current (I_{DS}) at a voltage 5V greater than the threshold voltage (Vth).

Therefore, the thin film transistor 1300 according to an embodiment of the present disclosure has excellent on-current characteristics, and thus can be applied as a switching transistor (Switching TR) of an organic light emitting display apparatus. In addition, the thin film transistor 1300 according to an embodiment of the present disclosure may be applied as a driving thin film transistor (Driving TR) of an organic light emitting display apparatus.

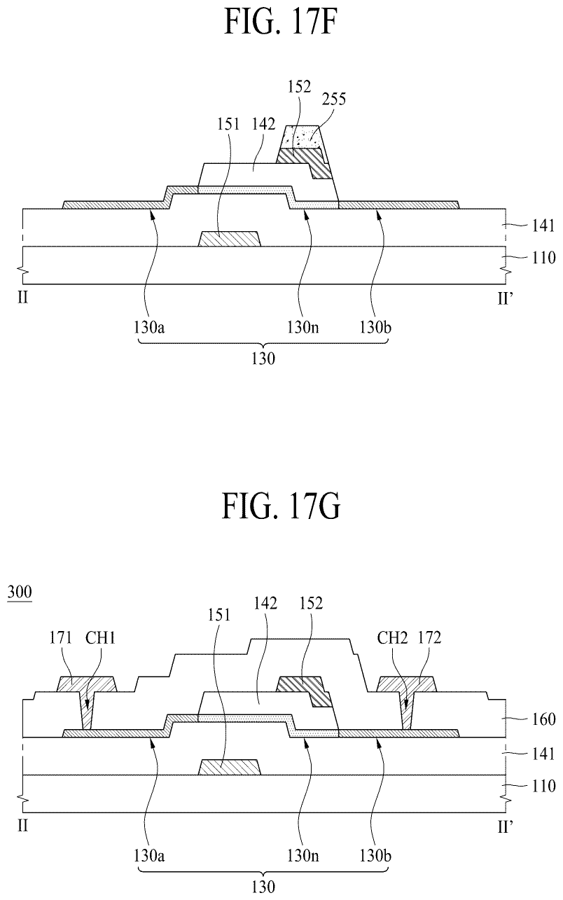

Hereinafter, with reference to FIGS. 17A to 17G, a method of manufacturing a thin film transistor 300 according to another embodiment of the present disclosure will be described.

17A to 17G are schematic process diagrams for a method of manufacturing a thin film transistor 300 according to an embodiment of the present disclosure.

Referring to FIG. 17A, a first gate electrode 151 is formed on the base substrate 110. Although not shown, a buffer layer 120 may be formed on the base substrate 110, and a first gate electrode 151 may be formed on the buffer layer 120.

Referring to FIG. 17B, a first gate insulating layer 141 is formed on the first gate electrode 151, and an active layer 130 is formed on the first gate insulating layer 141. The active layer 130 includes an oxide semiconductor material. The active layer 130 may be an oxide semiconductor layer.

Referring to FIG. 17C, a second gate insulating material layer 142m is formed on the active layer 130, and a second gate electrode material layer 152m is formed on the second gate insulating material layer 152m.

In addition, referring to FIG. 17C, a first photoresist pattern 250 is formed on the second gate electrode material layer 152m. The first photoresist pattern 250 can be formed by exposing and developing photoresist using half-tone mask.

Referring to FIG. 17D, the second gate electrode material layer 152m is etched using the first photoresist pattern 250 as a mask. As a result, the second gate electrode pattern 152p is formed.

In the process of forming the second gate electrode pattern 152p, the second gate insulating material layer 142m may be etched to form the second gate insulating layer 142. For example, the second gate insulating layer 142 may be formed by etching process using the second gate electrode pattern 152p as a mask. However, another embodiment of the present disclosure is not limited thereto, and the second gate insulating layer 142 may not be patterned.

Referring to FIG. 17D, the active layer 130 may be selectively conductorized. In the process of forming the second gate insulating layer 142, the active layer 130 may be selectively conductorized. Alternately, after the second gate insulating layer 142 is formed, the active layer 130 may be selectively conductorized by a separate process.

For example, the active layer 130 may be selectively doped with a dopant.

Referring to FIG. 17D, the active layer 130 may be selectively conductorized by doping process using the first photoresist pattern 250 and the second gate electrode pattern 152p as a mask. A region of the active layer 130 that is not protected by the second gate electrode pattern 152p may be selectively conductorized.

The dopant may include at least one of boron (B), phosphorus (P), and fluorine (F). The dopant may be doped in an ionic state. According to an embodiment of the present disclosure, selective conductorization can be achieved by ion doping through ion implantation.

However, an embodiment of the present disclosure is not limited thereto, and the active layer 130 may be selectively conductorized during a plasma processing for forming the second gate insulating layer 142.

Referring to FIG. 17D, as a result of selective conductorization to the active layer 130, a first connection portion 130a and a second connection portion 130b are formed. According to an embodiment of the present disclosure, the channel portion 130n of the active layer 130 is not conductorized.

Referring to FIG. 17E, a portion of the first photoresist pattern 250 is removed to form the second photoresist pattern 255.

Referring to FIG. 17F, the second gate electrode pattern 152p is etched by etching process using the second photoresist pattern 255 as a mask to form the second gate electrode 152. After forming the second gate electrode 152, the second photoresist pattern 255 is removed.

Referring to FIG. 17G, after the second photoresist pattern 255 is removed, an interlayer insulating film 160 is formed on the second gate electrode 152, and a source electrode 171 and a drain electrode 172 are formed on the interlayer insulating film 160. The source electrode 171 and the drain electrode 172 are spaced apart from each other and connected to the active layer 130 respectively.

Hereinafter, a display apparatus according to another embodiment of the present disclosure will be described. A display apparatus according to another embodiment of the present disclosure may include at least one of the thin film transistors 100, 200, 300, 400, 500, 600, 700, 800, 900, 1000, 1100, 1200, 1300 described above.

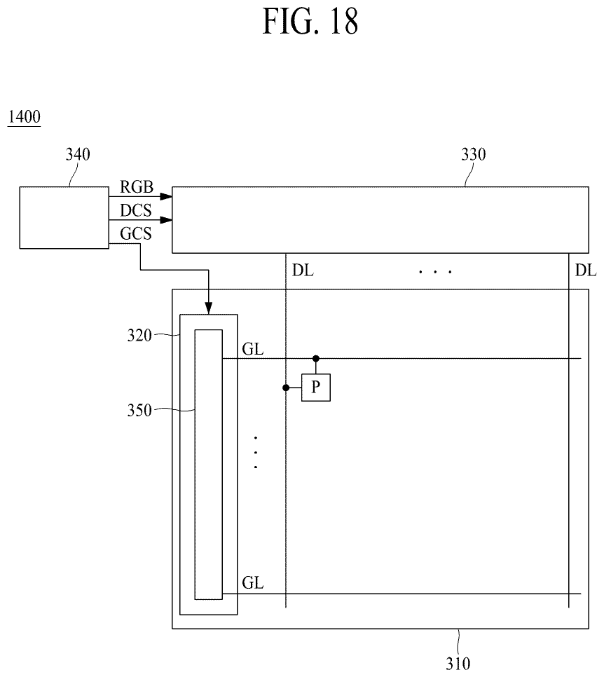

FIG. 18 is a schematic diagram of a display apparatus 1400 according to another embodiment of the present disclosure.

The display apparatus 1400 according to another embodiment of the present disclosure may include a display panel 310, a gate driver 320, a data driver 330, and a controller 340.

In some embodiments of the present disclosure, for convenience of explanation, a source region and a source electrode are distinguished, and a drain region and a drain electrode are distinguished, but the embodiments of the present disclosure are not limited thereto. The source region may be a source electrode, and the drain region may be a drain electrode. In addition, the source region may be a drain electrode, and the drain region may be a source electrode.

The controller 340 controls the gate driver 320 and data driver 330.

The controller 340 uses, for example, a signal supplied from an external system (not shown) to generate a gate control signal GCS to control the gate driver 320 and a data control signal DCS to control the data driver 330. In addition, the controller 340 samples input image data input from an external system, realigns it, and supplies the realigned digital image data RGB to the data driver 330.

The gate control signal GCS includes a gate start pulse GSP, gate shift clock GSC, gate output enable signal GOE, start signal Vst, and gate clock G_{CLK}. In addition, the gate control signal GCS may include control signals for controlling the shift register 350.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

The gate driver 320 may include a shift register 350. The shift register 350 sequentially supplies gate pulses to the gate lines GL for one frame using a start signal and gate clock transmitted from the controller 340.

Using the shift register 350, the gate driver 320 can sequentially supply gate pulses GP to the gate lines GL during one frame. Here, one frame refers to the period during which one image is output through the display panel. In addition, the gate driver 320 supplies a gate off signal G_{off} that can turn off the switching element to the gate line GL during the remaining period in one frame in which the gate pulse GP is not supplied. Hereinafter, the gate pulse GP and the gate off signal G_{off} are collectively referred to as the scan signal SS.

According to an embodiment of the present disclosure, the gate driver 320 may be mounted in the display panel 310. In this way, the structure in which the gate driver 320 is directly mounted in the display panel 310 is called a gate in panel GIP structure.

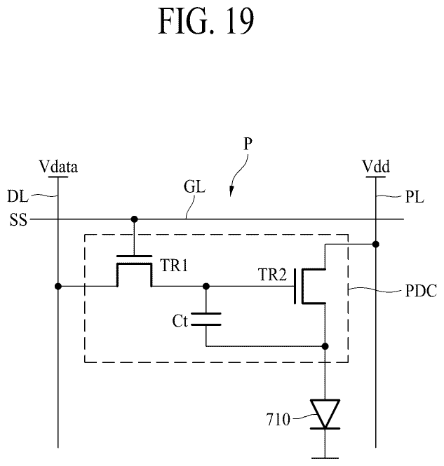

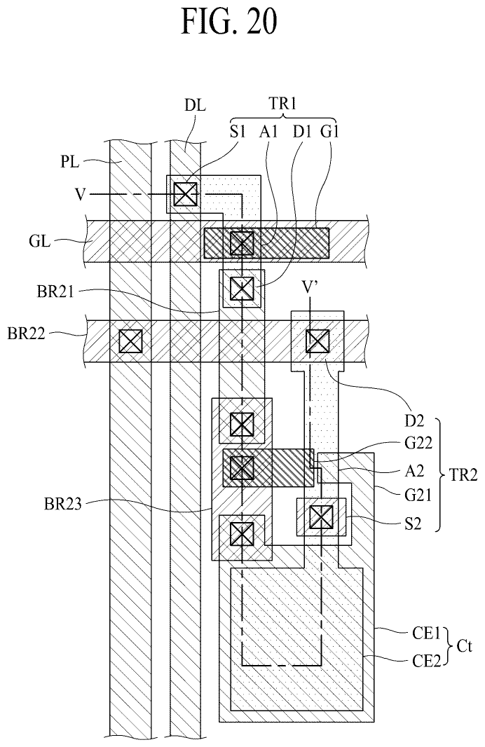

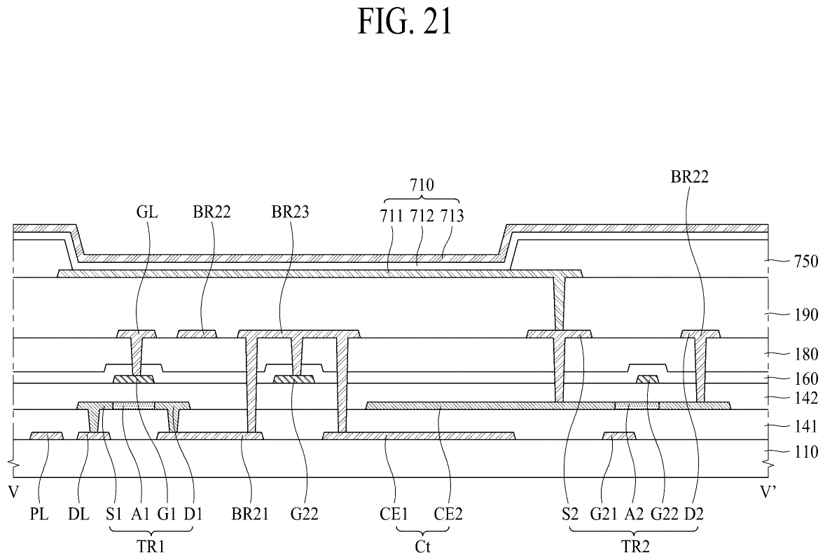

FIG. 19 is a circuit diagram of a pixel P of FIG. 18, FIG. 20 is a plan view of the pixel P of FIG. 19, and FIG. 21 is a cross-sectional view along a line V-V′ of FIG. 20.

The circuit diagram of FIG. 19 is an equivalent circuit diagram for a pixel P of the display apparatus 1400 including an organic light emitting diode OLED as a display element 710.

The display apparatus 1400 includes a pixel driving circuit PDC and a display element 710 connected to the pixel driving circuit PDC. The pixel driving circuit PDC may include at least one of the thin film transistors 100, 200, 300, 400, 500, 600, 700, 800, 900, 1000, 1100, 1200, and 1300 described above.

The pixel driving circuit PDC and the display element 710 are disposed in each pixel P. The pixel P includes the display element 710 and the pixel driving circuit PDC that drives the display element 710. The pixel driving circuit PDC may include a first thin film transistor TR1 and a second thin film transistor TR2.

The first thin film transistor TR1 is connected to the gate line GL and the data line DL, and is turned on or off by the scan signal SS supplied through the gate line GL.

The data line DL provides the data voltage Vdata to the pixel driving circuit PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

The thin film transistors described above may be applied as the first thin film transistor TR1 or the second thin film transistor TR2 of FIG. 19. In particular, as the second thin film transistor TR2, which is a driving transistor, the thin film transistors 100, 200, 300, 400, 500, 600, 700, 800, 900, 1000, 1100, 1200, 1300 described above may be applied.

When the first thin film transistor TR1 is turned on by the scan signal SS applied from the gate driver 320 through the gate line GL, the data voltage Vdata supplied from the data line DL is supplied to the gate electrode of the second thin film transistor TR2 connected to the display element 710. The data voltage Vdata is charged in the capacitor Ct formed between the gate electrode and the source electrode of the second thin film transistor TR2. The capacitor Ct of FIG. 19 is a storage capacitor.

The amount of current supplied to the organic light emitting diode OLED, which is the display element 710, through the second thin film transistor TR2 is controlled according to the data voltage Vdata, whereby a gray scale of light emitted from the display element 710 may be controlled.

Referring to FIGS. 20 and 21, the first thin film transistor TR1 and the second thin film transistor TR2 are disposed on a base substrate 110.

The base substrate 110 may be made of glass or plastic. As the base substrate 110, a plastic with flexible properties, for example, polyimide (PI), may be used.

Referring to FIG. 21, a data line DL, a driving power line PL, and a first bridge electrode BR21 may be disposed on the base substrate 110. In addition, a first gate electrode G21 of the second thin film transistor TR2 and a first capacitor electrode CE1 may be disposed on the base substrate 110.

Referring to FIGS. 20 and 21, the first gate electrode G21 of the second thin film transistor TR2 and the first capacitor electrode CE1 may be formed integrally one body. For example, the first gate electrode G21 of the second thin film transistor TR2 may be extended to become the first capacitor electrode CE1.

Although not shown, a light shielding layer may be disposed on the base substrate 110. The light shielding layer may be disposed to overlap the channel portion of the active layer A1, A2.

A first gate insulating layer 141 is disposed on the first capacitor electrode CE1, the data line DL, the driving power line PL, the first bridge electrode BR21, and the first gate electrode G21 of the second thin film transistor TR2. The first gate insulating layer 141 is made of an insulating material and may have dielectric properties. In addition, the first gate insulating layer 141 may serve to protect the channel portion of the active layers A1 and A2 from moisture or oxygen permeated from outside.

Active layers A1 and A2 are disposed on the first gate insulating layer 141. Each of the active layers A1 and A2 may include an oxide semiconductor material. Each of the active layers A1 and A2 may include an oxide semiconductor layer made of an oxide semiconductor material.

Each of the active layers A1 and A2 may include a channel portion, a first connection portion, and a second connection portion. The first connection portion may serve as a source connection, and the second connection portion may serve as a drain connection. Referring to FIGS. 20 and 21, the first connection portion of the first thin film transistor TR1 may be the source electrode S1, and the second connection portion of the first thin film transistor TR1 may be the drain electrode D1.

A portion of the active layer A2 of the second thin film transistor TR2 may be conductorized to become a second capacitor electrode CE2. The second capacitor electrode CE2 overlaps the first capacitor electrode CE1. A capacitor Ct is formed by the first capacitor electrode CE1 and the second capacitor electrode CE2.

The source electrode SI of the first thin film transistor TR1 may be connected to the data line DL through a contact hole. The drain electrode DI of the first thin film transistor TR1 may be connected to the first bridge electrode BR21 through a contact hole.

A second gate insulating layer 142 is disposed on the active layers A1 and A2 and the second capacitor electrode CE2. The second gate insulating layer 142 has insulating properties. The second gate insulating layer 142 may cover the entire upper surface over the active layers A1 and A2.

A gate electrode G1 of the first thin film transistor TR1 and a second gate electrode G22 of the second thin film transistor TR2 are disposed on the second gate insulating layer 142.

An interlayer insulating film 160 is disposed on the gate electrode G1 of the first thin film transistor TR1 and the second gate electrode G22 of the second thin film transistor TR2. A passivation layer 180 is disposed on the interlayer insulating film 160. The interlayer insulating film 160 and the passivation layer 180 protect the thin film transistors TR1 and TR2.

On the passivation layer 180, a gate line GL, bridge electrodes BR22 and BR23, and a source electrode S2 and a drain electrode D2 of the second thin film transistor TR2 are disposed.

The gate line GL is connected to the gate electrode G1 of the first thin film transistor TR1 through a contact hole. Accordingly, a scan signal SS may be applied to the gate electrode G1 of the first thin film transistor TR1.

The second bridge electrode BR22 is disposed on the passivation layer 180 and connects the driving power line PL and the active layer A2 of the second thin film transistor TR2. Referring to FIG. 20, one side of the second bridge electrode BR22 is connected to the driving power line PL through a contact hole, and the other side of the second bridge electrode BR22 is connected to active layer A2 of the second thin film transistor TR2 through a contact hole.

The other side of the second bridge electrode BR22 connected to the active layer A2 of the second thin film transistor TR2 may serve as the drain electrode D2 of the second thin film transistor TR2. Accordingly, the driving voltage Vdd may be applied to the drain electrode D2 of the second thin film transistor TR2.

The source electrode S2 of the second thin film transistor TR2 is disposed on the passivation layer 180 and is connected to the active layer A2 of the second thin film transistor TR2 through a contact hole. In addition, the source electrode S2 of the second thin film transistor TR2 is connected to the second capacitor electrode CE2. As a result, the same voltage as a voltage of the source electrode S2 of the second thin film transistor TR2 may be applied to the second capacitor electrode CE2.

The third bridge electrode BR23 is disposed on the passivation layer 180 and connects the first bridge electrode BR21, the second gate electrode G22 of the second thin film transistor TR2, and the first capacitor electrode CE1 each other.

The first bridge electrode BR21 is connected to the drain electrode DI of the first thin film transistor TR1, and the third bridge electrode BR23 is connected to the first bridge electrode BR21. As a result of this connection, the data voltage Vdata transmitted to the drain electrode DI through the first thin film transistor TR1 can be transmitted to the second gate electrode G22 of the second thin film transistor TR2 through the first bridge electrode BR21 and the third bridge electrode BR23.

In addition, the third bridge electrode BR23 is connected to the first capacitor electrode CE1 through a contact hole. As a result, the same voltage as a voltage of the second gate electrode G22 of the second thin film transistor TR2 may be applied to the first capacitor electrode CE1 through the third bridge electrode BR23. In addition, the same voltage as the voltage of second gate electrode G22 of the second thin film transistor TR2 can be applied to the first gate electrode G21 of the second thin film transistor TR2 formed integrally with the first capacitor electrode CE1.

A planarization layer 190 is disposed on the gate line GL, the bridge electrodes BR22 and BR23, and the source electrode S2 and drain electrode D2 of the second thin film transistor TR2. The planarization layer 190 planarizes the upper portions of the first thin film transistor TR1 and the second thin film transistor TR2 and protects the first thin film transistor TR1 and the second thin film transistor TR2.

The first electrode 711 of the display element 710 is disposed on the planarization layer 190. The first electrode 711 of the display element 710 may be connected to the source electrode S2 of the second thin film transistor TR2 through a contact hole formed in the planarization layer 190.

A bank layer 750 is disposed at the edge of the first electrode 711. The bank layer 750 defines a light-emitting area of the display element 710.

An organic light emission layer 712 is disposed on the first electrode 711, and a second electrode 713 is disposed on the organic light emission layer 712. Accordingly, the display element 710 is completed. The display element 710 illustrated in FIG. 21 is an organic light emitting diode OLED. Accordingly, the display apparatus 1400 according to an embodiment of the present disclosure is an organic light emitting display apparatus.

Even though FIGS. 19 to 21 describes a 2TR1C structure in which the pixel driving circuit PDC has two transistors and one capacitor, the present disclosure is not limited thereto. The pixel driving circuit PDC according to another embodiment of the present disclosure may be formed in various structures other than those described above. The pixel driving circuit PDC may include, for example, three or more thin film transistors and two or more capacitors.

The present disclosure described above is not limited to the above-described embodiments and the accompanying drawings, and it is well known to those with ordinary knowledge that various substitutions, modifications, and changes are possible within the scope of the technical details of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
a first gate electrode;
a first gate insulating layer on the first gate electrode;
an active layer on the first gate insulating layer;
a second gate insulating layer on the active layer; and
a second gate electrode on the second gate insulating layer,
wherein the active layer includes:
a channel portion;
a first connection portion contacting one side of the channel portion; and
a second connection portion contacting the other side of the channel portion,
wherein the channel portion includes:
a first channel portion overlapping the first gate electrode; and
a second channel portion overlapping the second gate electrode,
wherein the first gate electrode and the second gate electrode do not overlap each other in a plan view.

2. The thin film transistor according to claim 1, wherein the first channel portion does not overlap the second gate electrode, and
wherein the second channel portion does not overlap the first gate electrode.

3. The thin film transistor according to claim 1, wherein the first gate electrode and the second gate electrode are spaced apart from each other in a plan view.

4. The thin film transistor according to claim 3, wherein the first channel portion and the second channel portion are spaced apart from each other.

5. The thin film transistor according to claim 3, wherein a separation distance between the first gate electrode and the second gate electrode is 0 to 1 μm in a plan view.

6. The thin film transistor according to claim 3, wherein a separation distance between the first channel portion and the second channel portion is 0 to 1 μm.

7. The thin film transistor according to claim 1, wherein the first gate insulating layer has a thickness of 2 to 3 times a thickness of the second gate insulating layer.

8. The thin film transistor according to claim 1, wherein a ratio of a width of the first channel portion to a width of the second channel portion is in a range of 8:2 to 2:8, and
wherein a direction connecting the first connection portion and the second connection portion in a plan view is a longitudinal direction of the channel portion, and a direction perpendicular to the longitudinal direction of the channel portion is a width direction of the channel portion.

9. The thin film transistor according to claim 8, wherein the ratio of a length of the first channel portion to a length of the second channel portion is in a range of 1:2 to 2:1.

10. The thin film transistor according to claim 8, wherein the width of the first channel portion is greater than the width of the second channel portion.

11. The thin film transistor according to claim 10, wherein a length of the first channel portion is smaller than a length of the second channel portion.

12. The thin film transistor according to claim 10, wherein a length of the first channel portion is greater than a length of the second channel portion.

13. The thin film transistor according to claim 10, wherein the first channel portion and the second channel portion have a same length.

14. The thin film transistor according to claim 8, wherein the first channel portion and the second channel portion have a same width.

15. The thin film transistor according to claim 8, wherein the width of the first channel portion is smaller than the width of the second channel portion.

16. The thin film transistor according to claim 15, wherein the first channel portion has a length greater than a length of the second channel portion.

17. The thin film transistor according to claim 1, wherein the active layer comprises at least one of IGZO (InGaZnO)-based oxide semiconductor material, IZO (InZnO)-based oxide semiconductor material, ITZO (InSnZnO)-based oxide semiconductor material, FIZO (FeInZnO)-based oxide semiconductor material, ZnO-based oxide semiconductor material, SIZO (SiInZnO)-based oxide semiconductor material, ZnON (Zn-Oxynitride)-based oxide semiconductor material, GZO (GaZnO)-based oxide semiconductor material, IGO (InGaO)-based oxide semiconductor material, IGZTO (InGaZnSnO)-based oxide semiconductor material, GZTO (GaZnSnO)-based oxide semiconductors, and IWZO (InWZnO)-based oxide semiconductor material.

18. The thin film transistor according to claim 1, wherein the active layer comprises:
a first oxide semiconductor layer; and
a second oxide semiconductor layer on the first oxide semiconductor layer, and
wherein the second oxide semiconductor layer is disposed closer to the second gate electrode than the first oxide semiconductor layer, and has a greater mobility than a mobility of the first oxide semiconductor layer.

19. A display apparatus comprising:
a pixel driving circuit; and
a display element connected to the pixel driving circuit,
wherein the pixel driving circuit includes a thin film transistor,
wherein the thin film transistor includes:
a first gate electrode;
a first gate insulating layer on the first gate electrode;
an active layer on the first gate insulating layer;
a second gate insulating layer on the active layer; and
a second gate electrode on the second gate insulating layer,
wherein the active layer includes:
a channel portion;
a first connection portion contacting one side of the channel portion; and
a second connection portion contacting the other side of the channel portion,
wherein the channel portion includes:
a first channel portion overlapping the first gate electrode; and
a second channel portion overlapping the second gate electrode,
wherein the first gate electrode and the second gate electrode do not overlap each other in a plan view.

20. The display apparatus according to claim 19, wherein the pixel driving circuit includes a driving transistor and a switching transistor, and
wherein the thin film transistor is the driving transistor.
